(19) United States
(12) Patent Application Publication
(10) Pub. No.: US 2023/0101791 A1
(43) Pub. Date: Mar. 30, 2023

(54) THERMOSETTING RESIN COMPOSITION, RESIN SHEET, METAL FOIL WITH RESIN, METAL-CLAD LAMINATE, AND PRINTED WIRING BOARD

(71) Applicant: Panasonic Intellectual Property Management Co., Ltd., Osaka (JP)

(72) Inventors: Kouichi AOKI, Hyogo (JP); Tomoyuki AOKI, Fukushima (JP)

(73) Assignee: Panasonic Intellectual Property Management Co., Ltd., Osaka (JP)

(21) Appl. No.: 17/800,109

(22) PCT Filed: Feb. 15, 2021
(86) PCT No.: PCT/JP2021/005513

§ 371 Date: Aug. 16, 2022

(30) Foreign Application Priority Data
Feb. 18, 2020 (JP) 2020-025535

(51) Int. Cl. C08L 71/12; C08L 9/06; B32B 15/08; C08L 57/10

(52) U.S. Cl. CPC C08L 71/12; C08L 9/06; B32B 15/08; C08L 57/10; C08L 2201/00; C08L 2203/30; C08L 2207/04

(57) ABSTRACT

A thermosetting resin composition contains an ethylene-propylene-diene copolymer (A), a terminal-modified polyphenylene ether compound (B), an inorganic filler (C), a styrene-based elastomer (D), and a fibrous filler (E).

### TECHNICAL FIELD

The present disclosure generally relates to a thermosetting resin composition, a resin sheet, a sheet of metal foil with resin, a metal-clad laminate, and a printed wiring board. More particularly, the present disclosure relates to a thermosetting resin composition containing an ethylene-propylene-diene copolymer and a terminal-modified polyphenylene ether compound, a resin sheet and a sheet of metal foil with resin, each including an uncured product or semi-cured product of the thermosetting resin composition, and a metal-clad laminate and a printed wiring board, each including a cured product of the thermosetting resin composition.

### BACKGROUND ART

Various techniques for conveying information at even higher speeds have been developed continuously. To obtain a printed wiring board with the capability of processing such high-speed signals for such purposes, there has been an increasing demand for further lowering the dielectric constant and dielectric loss tangent of an insulating layer of the printed wiring board.

For example, Patent Literature 1 discloses, as a material for an insulating layer of a printed wiring board, a thermosetting adhesive composition. The composition of Patent Literature 1 contains, at a predetermined ratio: a vinyl compound having a polyphenylene ether skeleton; a maleimide resin having two or more maleimide groups; and an elastomer composed mainly of a polyphenylene skeleton and serving as a copolymer of a polyolefin block and a polystyrene block. Patent Literature 1 describes that an insulating layer made of this thermosetting adhesive composition has a low dielectric constant and a low dielectric loss tangent, exhibits high adhesive strength to an LCP film and copper foil, and has high heat resistance.

### CITATION LIST

### Patent Literature

Patent Literature 1: WO 2016/117554 A1

### SUMMARY OF INVENTION

When an insulating layer is formed for a printed wiring board, a resin sheet or any other material, obtained by forming an uncured product or semi-cured product of a thermosetting composition into a sheet shape, is cured. The present inventors discovered, as a result of our investigation, that if the material such as a resin sheet had low flexibility and low strength, the handleability of the material such as a resin sheet was so poor in the process step of forming the insulating layer that the material such as a resin sheet tended to be easily torn and damaged.

The problem to be overcome by the present disclosure is to provide: a thermosetting resin composition which makes it easier to not only lower the dielectric constant and dielectric loss tangent of the insulating layer but also increase the flexibility and strength of the resin sheet; a resin sheet and a sheet of metal foil with resin, each including an uncured product or semi-cured product of the thermosetting resin composition; and a metal-clad laminate and printed wiring board, each including a cured product of the thermosetting resin composition.

A thermosetting resin composition according to an aspect of the present disclosure contains an ethylene-propylene-diene copolymer (A), a terminal-modified polyphenylene ether compound (B), an inorganic filler (C), a styrene-based elastomer (D), and a fibrous filler (E).

A resin sheet according to another aspect of the present disclosure contains an uncured product or semi-cured product of the thermosetting resin composition described above.

A sheet of metal foil with resin according to still another aspect of the present disclosure includes a sheet of metal foil and a resin layer laid on top of the sheet of metal foil. The resin layer contains an uncured product or semi-cured product of the thermosetting resin composition described above.

A sheet of metal foil with resin according to yet another aspect of the present disclosure includes: a sheet of metal foil; a first resin layer stacked on the sheet of metal foil; and a second resin layer stacked on the first resin layer. The first resin layer contains at least one component selected from the group consisting of a liquid crystal polymer resin, a polyimide resin, a polyamide imide resin, a fluorocarbon resin, and a polyphenylene ether resin. The second resin layer contains an uncured product or semi-cured product of the thermosetting resin composition described above.

A metal-clad laminate according to yet another aspect of the present disclosure includes an insulating layer and a sheet of metal foil laid on top of the insulating layer. The insulating layer contains a cured product of the thermosetting resin composition described above.

A printed wiring board according to yet another aspect of the present disclosure includes an insulating layer and conductor wiring. The insulating layer includes a cured product of the thermosetting resin composition described above.

### BRIEF DESCRIPTION OF DRAWINGS

FIG. 1A is a schematic representation illustrating an exemplary sheet of metal foil with resin according to an exemplary embodiment of the present disclosure;

FIG. 1B is a schematic representation illustrating another exemplary sheet of metal foil with resin according to the exemplary embodiment of the present disclosure;

FIG. 1C is a schematic representation illustrating still another exemplary sheet of metal foil with resin according to the exemplary embodiment of the present disclosure;

FIG. 2A is a schematic representation illustrating an exemplary metal-clad laminate according to an exemplary embodiment of the present disclosure;

FIG. 2B is a schematic representation illustrating another exemplary metal-clad laminate according to the exemplary embodiment of the present disclosure;

FIG. 2C is a schematic representation illustrating still another exemplary metal-clad laminate according to the exemplary embodiment of the present disclosure;

FIG. 2D is a schematic representation illustrating yet another exemplary metal-clad laminate according to the exemplary embodiment of the present disclosure;

FIG. 3A is a schematic representation illustrating an exemplary printed wiring board according to an exemplary embodiment of the present disclosure;

FIG. 3B is a schematic representation illustrating another exemplary printed wiring board according to the exemplary embodiment of the present disclosure;

FIG. 3C is a schematic representation illustrating still another exemplary printed wiring board according to the exemplary embodiment of the present disclosure; and

FIG. 3D is a schematic representation illustrating yet another exemplary printed wiring board according to the exemplary embodiment of the present disclosure.

### DESCRIPTION OF EMBODIMENTS

An exemplary embodiment of the present disclosure will now be described.

A thermosetting resin composition according to an exemplary embodiment (hereinafter referred to as “composition (X)”) contains an ethylene-propylene-diene copolymer (A), a terminal-modified polyphenylene ether compound (B), an inorganic filler (C), a styrene-based elastomer (D), and a fibrous filler (E).

According to this embodiment, the composition (X) contains the ethylene-propylene-diene copolymer (A), the terminal-modified polyphenylene ether compound (B), and the inorganic filler (C). This makes it easier to lower the dielectric constant and dielectric loss tangent of a cured product made of the composition (X). The ethylene-propylene-diene copolymer (A), the terminal-modified polyphenylene ether compound (B), and the inorganic filler (C) tend to lower the plasticity and strength of a resin sheet made of the composition (X). This will normally cause a decline in the handleability of the resin sheet, thus often causing damage such as a tear to the resin sheet. According to this embodiment, however, the composition (X) further contains the styrene-based elastomer (D) and the fibrous filler (E). This makes it easier to increase the plasticity and strength of the resin sheet. Consequently, this reduces the chances of causing a decline in the handleability of the resin sheet and causing damage such as a tear to the resin sheet. Therefore, this embodiment contributes to increasing the handleability of the resin sheet and reduces the chances of causing damage such as a tear to the resin sheet.

The composition (X) will be described in further detail.

As described above, the composition (X) contains an ethylene-propylene-diene copolymer (A), a terminal-modified polyphenylene ether compound (B), an inorganic filler (C), a styrene-based elastomer (D), and a fibrous filler (E).

The ethylene-propylene-diene copolymer (A) (hereinafter simply referred to as a “copolymer (A)”) is generally also called “EPDM (ethylene-propylene-diene monomer) rubber.” The copolymer (A) has a structural unit derived from ethylene (hereinafter referred to as an “ethylene unit”), a structural unit derived from propylene (hereinafter referred to as a “propylene unit”), and a structural unit derived from diene (hereinafter referred to as a “diene unit”). The diene unit preferably includes a structural unit derived from 5-ethylidene-2-norbornene (hereinafter simply referred to as “5-ethylidene-2-norbornene unit”). That is to say, the ethylene-propylene-diene copolymer (A) preferably includes the component expressed by the following Formula (1), where n, m, and 1 are natural numbers indicating the numbers of structural units in Formula (1). Therefore, Formula (1) is a compositional formula indicating the proportions of the respective structural units. That is to say, Formula (1) indicates that the copolymer (A) includes the ethylene unit, the propylene unit, and the diene unit at a molar ratio of n:m:1. The 5-ethylidene-2-norbornene unit as the diene unit contributes to increasing the curing reaction rate of the composition (X), thus shortening the time it takes to cure the composition (X). Note that the structural unit included in the diene unit is not necessarily the 5-ethylidene-2-norbornene unit. Alternatively, the diene unit may also include at least one structural unit selected from the group consisting of a dicyclopentadiene unit and a 1,4-hexadiene unit.

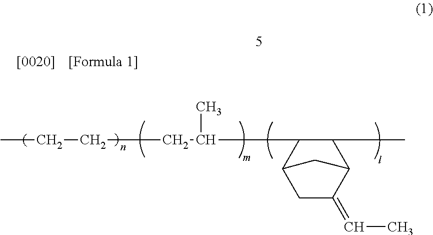

The percentage by mass of the diene unit to the entire copolymer (A) is preferably equal to or greater than 3%, which would contribute to improving the heat resistance of the cured product. The percentage by mass of the diene unit is more preferably equal to or greater than 3% and equal to or less than 15%.

The percentage by mass of the ethylene unit to the entire copolymer (A) is preferably equal to or greater than 50%. This makes it easier to form the composition (X) into a sheet shape. The percentage by mass of the ethylene unit is more preferably equal to or greater than 50% and equal to or less than 75%.

The Mooney viscosity ML (1+4) 100° C. of the copolymer (A) as defined by JIS K6300-1:2013 is preferably equal to or greater than 10. This also allows the composition (X) to be easily formed into a sheet shape, and allows the molded product obtained by forming the composition into the sheet shape to have reduced tackiness. The Mooney viscosity ML (1+4) 125° C. of the copolymer (A) as defined by JIS K6300-1:2013 is more preferably equal to or less than 80. Setting the Mooney viscosity at 80 or less may prevent the melt viscosity of the copolymer (A) from becoming too high and may improve the moldability of the cured product.

Note that the Mooney viscosity of the copolymer (A) increases as the molecular weight of the copolymer (A) increases. Therefore, the Mooney viscosity may be adjusted by adjusting the molecular weight of the molecules contained in the copolymer (A), adding molecules having different molecular weights to the copolymer (A), mixing the molecules together, and adjusting the mixing ratio thereof, and/or adjusting the molecules contained in the copolymer (A) into a branched structure.

The content of the copolymer (A) in the composition (X) is preferably equal to or greater than 50 parts by mass and equal to or less than 200 parts by mass with respect to 100 parts by mass of the terminal-modified polyphenylene ether compound (B). Setting the content of the copolymer (A) at 50 parts by mass or more makes it easier to form a film out of the composition (X) and further lower the dielectric constant of the cured product of the composition (X). Setting the content of the copolymer (A) at 200 parts by mass or less makes it easier to lower the coefficient of thermal expansion of the cured product of the composition (X) and thereby improve the heat resistance of the cured product.

The terminal-modified polyphenylene ether compound (B) (hereinafter simply referred to as the “compound (B)”) is a polyphenylene ether which is terminal-modified with a substituent having a carbon-carbon unsaturated double bond. That is to say, the compound (B) has, for example, a polyphenylene ether chain and a substituent having a carbon-carbon unsaturated double bond bonded to the terminal of the polyphenylene ether chain.

An exemplary substituent having a carbon-carbon unsaturated double bond in the compound (B) is expressed by the following Formula (2). Note that this is only an exemplary substituent and should not be construed as limiting.

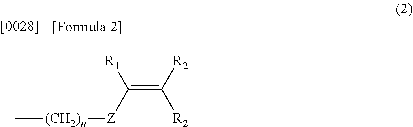

where n is a number falling within the range from 0 to 10, Z is an arylene group, and R₁ to R₃ each independently represent a hydrogen atom or an alkyl group. In Formula (2), if n is zero, then Z is directly bonded to a terminal of a polyphenylene ether chain.

The arylene group may be, for example, a monocyclic aromatic group such as a phenylene group or a polycyclic aromatic group such as a naphthylene group. At least one hydrogen atom bonded to the aromatic ring of the arylene group may be replaced with a functional group such as an alkenyl group, an alkynyl group, a formyl group, an alkylcarbonyl group, an alkenylcarbonyl group, or an alkynylcarbonyl group. The alkyl group is not limited to any particular one but is preferably an alkyl group having 1 to 18 carbon atoms, and more preferably an alkyl group having 1 to 10 carbon atoms. Specifically, the alkyl group may be, for example, a methyl group, an ethyl group, a propyl group, a hexyl group, or a decyl group.

More specifically, the substituent having a carbon-carbon unsaturated double bond may have, for example: a vinylbenzyl group (ethenylbenzyl group) such as a p-ethenylbenzyl group or an m-ethenylbenzyl group; a vinylphenyl group; an acrylate group; or a methacrylate group. The substituent having a carbon-carbon unsaturated double bond preferably has a vinylbenzyl group, a vinylphenyl group, or a methacrylate group, among other things. If the substituent having a carbon-carbon unsaturated double bond has an allyl group, the reactivity of the compound (B) tends to be low. Meanwhile, if the substituent having a carbon-carbon unsaturated double bond has an acrylate group, the reactivity of the compound (B) tends to be too high.

A preferred specific example of the substituent having a carbon-carbon unsaturated double bond may be a functional group including a vinylbenzyl group. Specifically, the substituent expressed by Formula (2) may be, for example, a substituent expressed by the following Formula (3) or the following Formula (4):

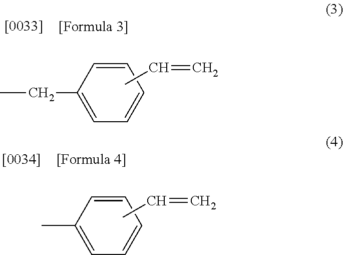

The substituent having a carbon-carbon unsaturated double bond may also be a (meth)acrylate group. The (meth)acrylate group is expressed by, for example, the following Formula (5):

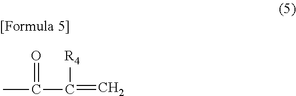

In Formula (5), R₄ is a hydrogen atom or an alkyl group. The alkyl group preferably has 1 to 18 carbon atoms, and more preferably has 1 to 10 carbon atoms. However, this is only an example and should not be construed as limiting. For example, the alkyl group may be a methyl group, an ethyl group, a propyl group, a hexyl group, or a decyl group.

The polyphenylene ether chain in the compound (B) may have, for example, a skeleton expressed by the following Formula (6):

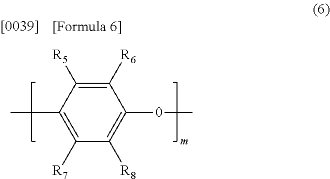

In Formula (6), m is a repeating unit, which may be, but does not have to be, a number falling within the range from 1-50. R₅ to R₈ each independently represent a hydrogen atom, an alkyl group, an alkenyl group, an alkynyl group, a formyl group, an alkylcarbonyl group, an alkenylcarbonyl group, or an alkynylcarbonyl group, for example. The alkyl group preferably has 1 to 18 carbon atoms, and more preferably has 1 to 10 carbon atoms. The alkyl group may be, for example, a methyl group, an ethyl group, a propyl group, a hexyl group, or a decyl group. The alkenyl group preferably has 2 to 18 carbon atoms, and more preferably has 2 to 10 carbon atoms. The alkenyl group may be, for example, a vinyl group, an allyl group, or a 3-butenyl group. The alkynyl group preferably has 2 to 18 carbon atoms, and more preferably has 2 to 10 carbon atoms. The alkynyl group may be, for example, an ethynyl group, or a prop-2-yn-1-yl group (propargyl group). The alkylcarbonyl group is a carbonyl group replaced with an alkyl group. The alkylcarbonyl group preferably has 2 to 18 carbon atoms, and more preferably has 2 to 10 carbon atoms. The alkylcarbonyl group may be, for example, an acetyl group, a propionyl group, a butyryl group, an isobutyryl group, a pivaloyl group, a hexanoyl group, an octanoyl group, or a cyclohexylcarbonyl group. The alkenylcarbonyl group is a carbonyl group replaced with an alkenyl group. The alkenylcarbonyl group preferably has 3 to 18 carbon atoms, and more preferably has 3 to 10 carbon atoms. The alkenylcarbonyl group may be, for example, an acryloyl group, a methacryloyl group, or a crotonoyl group. The alkynylcarbonyl group is a carbonyl group replaced with an alkynyl group. The alkynylcarbonyl group preferably has 3 to 18 carbon atoms, and more preferably has 3 to 10 carbon atoms. The alkynylcarbonyl group may be, for example, a propioloyl group. Each of R₅ to R₈ is more preferably a hydrogen atom or an alkyl group.

The weight mean molecular weight (Mw) of the compound (B) is preferably equal to or greater than 500 and equal to or less than 5000, more preferably equal to or greater than 500 and equal to or less than 2000, and even more preferably equal to or greater than 1000 and equal to or less than 2000. However, these values are only examples and should not be construed as limiting. The weight mean molecular weight is a value obtained by converting the result of measurement obtained by gel permeation chromatography (GPC) into an equivalent polystyrene weight. If the compound (B) has the skeleton expressed by Formula (6), the number m of repeating units in Formula (6) is preferably a value that makes the weight mean molecular weight of the compound (B) fall within any of the preferred ranges described above. Specifically, m is preferably equal to or greater than 1 and equal to or less than 50.

If the weight mean molecular weight of the compound (B) falls within such a range, the compound (B) is likely to impart excellent dielectric properties to the cured product of the composition (X) by the polyphenylene ether chain, thus improving the heat resistance of the cured product and the moldability of the composition (X) more easily. The reason is presumably as follows. If the weight mean molecular weight of normal polyphenylene ether is equal to or greater than about 500 and equal to or less than about 5000, the polyphenylene ether has a relatively low molecular weight, and therefore, tends to decrease the heat resistance of the cured product. On the other hand, the compound (B) has an unsaturated double bond at the terminal, and therefore, would improve the heat resistance of the cured product. Moreover, if the weight mean molecular weight of the compound (B) is equal to or less than 5000, the polyphenylene ether has a relatively low molecular weight, and therefore, would improve the moldability of the composition (X) more easily. Therefore, the compound (B) would improve not only the heat resistance of the cured product but also the moldability of the composition (X) as well. If the weight mean molecular weight of the compound (B) is equal to or greater than 500, the glass transition temperature of the cured product is unlikely to decrease, and therefore, the cured product tends to have good heat resistance. Furthermore, this reduces the chances of shortening the polyphenylene ether chain in the compound (B), thus allowing the cured product to maintain excellent dielectric properties due to the presence of the polyphenylene ether chain. Furthermore, if the weight mean molecular weight is equal to or less than 5000, the compound (B) is easily dissolved in a solvent, thus reducing the chances of causing a decline in the preservation stability of the composition (X). In addition, the compound (B) is unlikely to increase the viscosity of the composition (X), thus easily achieving good moldability for the composition (X).

The average number of substituents having a carbon-carbon unsaturated double bond (hereinafter also referred to as “the number of terminal functional groups”) per molecule of the compound (B) is preferably 1 to 5, more preferably 1 to 3, and even more preferably 1.5 to 3. This makes it easier to ensure sufficiently high heat resistance for the cured product of the composition (X) and reduces the chances of the reactivity and viscosity of the compound (B) becoming excessively high. In addition, this also reduces the chances of an unreacted unsaturated double bond remaining after the composition (X) has been cured. The number of terminal functional groups may be obtained, when the compound (B) is synthesized by modifying polyphenylene ether, for example, by measuring the number of hydroxyl groups in the compound (B) and calculating the decrease in the number of hydroxyl groups in the compound (B) from the number of hydroxyl groups in the polyphenylene ether yet to be modified. The decrease from the number of hydroxyl groups in the polyphenylene ether yet to be modified is the number of terminal functional groups. The number of hydroxyl groups remaining in the compound (B) may be determined by measuring the UV absorbance of a mixed solution obtained by adding a quaternary ammonium salt (tetraethylammonium hydroxide) associated with a hydroxyl group to a solution of the compound (B).

The intrinsic viscosity of the compound (B) is not limited to any particular value. Specifically, the intrinsic viscosity of the compound (B) may fall, for example, within the range from 0.03 dl/g to 0.12 dl/g, preferably falls within the range from 0.04 dl/g to 0.11 dl/g, and more preferably falls within the range from 0.06 dl/g to 0.095 dl/g. This makes it easier to lower the dielectric constant and dielectric loss tangent of the cured product of the composition (X). In addition, the moldability of the cured product may be improved by imparting sufficient flowability to the composition (X).

The intrinsic viscosity herein refers to an intrinsic viscosity measured in methylene chloride at 25° C. More specifically, the intrinsic viscosity is the viscosity at 25° C. of a solution prepared by dissolving the compound (B) in methylene chloride at a concentration of 0.18 g/45 ml. This viscosity is measured with, for example, a viscometer AVS500 Visco System manufactured by Schott.

The method for synthesizing the compound (B) is not limited to any particular one. For example, the compound (B) may be synthesized by allowing polyphenylene ether to react to a compound including a substituent having a carbon-carbon unsaturated double bond and a halogen atom. Examples of the compound including a substituent having a carbon-carbon unsaturated double bond and a halogen atom include p-chloromethylstyrene and m-chloromethylstyrene.

Polyphenylene ether as a raw material for synthesizing the compound (B) is not limited to any particular one. The polyphenylene ether contains at least one selected from the group consisting of a polyphenylene ether composed of 2,6-dimethylphenol and at least one of a bifunctional phenol and a trifunctional phenol, and a polyphenylene ether such as poly(2,6-dimethyl-1,4-phenylene oxide). As used herein, the bifunctional phenol is a phenol compound having two phenolic hydroxyl groups per molecule, and may be, for example, tetramethyl bisphenol A. The trifunctional phenol is a phenol compound having three phenolic hydroxyl groups per molecule.

Specifically, the compound (B) may be synthesized by dissolving, in a solvent, polyphenylene ether and a compound including a substituent having a carbon-carbon unsaturated double bond and a halogen atom and stirring up the mixture. This allows the polyphenylene ether to react to the compound including a substituent having a carbon-carbon unsaturated double bond and a halogen atom, thus forming the compound (B).

The inorganic filler (C) contributes to lowering the dielectric constant and dielectric loss tangent of the cured product. In addition, the inorganic filler (C) also contributes to improving the heat resistance, flame retardance, and tenacity of the cured product and reducing the coefficient of thermal expansion thereof.

Examples of the inorganic filler (C) include at least one material selected from the group consisting of silica, alumina, talc, aluminum hydroxide, magnesium hydroxide, titanium oxide, mica, aluminum borate, barium sulfate, boron nitride, forsterite, zinc oxide, magnesium oxide, and calcium carbonate. Note that these are only exemplary materials that may be included in the inorganic filler (C) and should not be construed as limiting.

The inorganic filler (C) preferably includes an inorganic filler (C1) subjected to surface treatment with a surface treatment agent having a polymerizable unsaturated bond. This causes the polymerizable unsaturated bond in the inorganic filler (C1) to react to the copolymer (A) and the compound (B), thus allowing the cured product to have an increased crosslink density. This reduces the chances of causing an increase in the dielectric loss tangent of the cured product of the composition (X) even if the cured product is left in an environment at a high temperature. Consequently, the dielectric loss tangent of an insulating layer made of the composition (X) is unlikely to increase in such a high-temperature environment.

The polymerizable unsaturated bond includes, for example, at least one group selected from the group consisting of a vinyl group, an allyl group, a methacrylic group, a styryl group, an acryloyl group, a methacryloyl group, and a maleimide group. Examples of the surface treatment agent include a silane coupling agent having a polymerizable unsaturated bond. However, this is only an example and should not be construed as limiting.

The content of the inorganic filler (C) in the composition (X) is preferably equal to or greater than 30 parts by mass and equal to or less than 500 parts by mass with respect to 100 parts by mass in total of the copolymer (A) and the compound (B). Setting the content of the inorganic filler (C) at 30 parts by mass or more allows the inorganic filler (C) to decrease the coefficient of linear expansion of the cured product particularly significantly, improve the dielectric properties of the cured product particularly easily, and improve the heat resistance and flame retardance of the cured product particularly significantly. Setting the content of the inorganic filler (C) at 500 parts by mass or less makes it easier for the composition (X) to maintain its flowability during molding.

The styrene-based elastomer (D) is a copolymer including, for example, an olefin unit and a styrene unit. The styrene-based elastomer (D) may increase the compatibility between the copolymer (A) and the compound (B) in the composition (X). Thus, the styrene-based elastomer (D) may improve the flame retardance of the cured product. In addition, the styrene-based elastomer (D) not only makes it easier to form the composition (X) into a film or sheet shape but also improves the tenacity of the film or the sheet.

The olefin unit means a structural unit derived from an olefin monomer, and the styrene unit means a structural unit derived from a styrene monomer. The styrene monomer is at least one selected from the group consisting of styrene and styrene having a substituent. The substituent is, for example, an alkyl group such as a methyl group. In particular, the styrene monomer preferably contains at least one of styrene or methylstyrene.

The styrene-based elastomer (D) may be a random copolymer or a block copolymer, whichever is appropriate.

The olefin unit in the styrene-based elastomer (D) preferably include at least one selected from the group consisting of an ethylene unit, a propylene unit, a butylene unit, an a-olefin unit, a butadiene unit, a hydrogenated butadiene unit, an isoprene unit, and a hydrogenated isoprene unit.

The mass ratio of the olefin unit and the styrene unit in the styrene-based elastomer (D) preferably falls within the range from 30:70 to 90:10, and more preferably falls within the range from 60:40 to 85:15. This makes it easier to improve the compatibility between the copolymer (A) and the compound (B).

If the styrene-based elastomer (D) is a random copolymer, the styrene-based elastomer (D) may be produced, for example, by polymerizing an olefin monomer and a styrene monomer by an emulsion polymerization method or a solution polymerization method.

If the styrene-based elastomer (D) is a block copolymer, the styrene-based elastomer (D) may be produced, for example, by block-polymerizing the olefin monomer and the styrene monomer in an inert solvent in the presence of a lithium catalyst.

The styrene-based elastomer (D) preferably contains a styrene-hydrogenated diene copolymer (D1) including a hydrogenated diene in the olefin unit. The styrene-hydrogenated diene copolymer (D1) is also called a “hydrogenated styrene elastomer.” The styrene-hydrogenated diene copolymer (D1) is a copolymer having a styrene unit and a hydrogenated diene unit. A hydrogenated diene unit is a unit derived from diene and hydrogenated. The hydrogenated diene unit includes, for example, at least one of a hydrogenated butadiene unit or a hydrogenated isoprene unit. Having the styrene-hydrogenated diene copolymer (D1) contained in the styrene-based elastomer (D) reduces the chances of the cured product of the composition (X) coming to have an increased dielectric loss tangent even when the cured product is left in a high-temperature environment. Therefore, the dielectric loss tangent of an insulating layer made of the composition (X) is unlikely to increase in a high-temperature environment.

The styrene-based elastomer (D) either contains no styrene-non-hydrogenated diene copolymer (D2) that contains a non-hydrogenated diene in the olefin unit and no hydrogenated diene or contains a styrene-non-hydrogenated diene copolymer (D2). In the latter case, it is preferable that the content of the styrene-non-hydrogenated diene copolymer (D2) to the styrene-based elastomer (D) be equal to or less than 5% by mass. The non-hydrogenated diene unit is a unit derived from diene and not hydrogenated. Specific examples of the non-hydrogenated diene unit include a butadiene unit and an isoprene unit. In that case, even if the cured product of the composition (X) is left in a high-temperature environment, the dielectric loss tangent of the cured product is even less likely to increase. This further reduces the chances of the dielectric loss tangent of an insulating layer made of the composition (X) increasing in a high-temperature environment.

The content of the styrene-based elastomer (D) is preferably equal to or greater than 5 parts by mass and equal to or less than 100 parts by mass with respect to 100 parts by mass in total of the copolymer (A) and the compound (B). Setting the content of the styrene-based elastomer (D) at 5 parts by mass or more makes it easier to improve the film-forming ability of the resin film. Setting the content of the styrene-based elastomer (D) at 100 parts by mass or less makes it easier to reduce an increase in the coefficient of thermal expansion of the cured product of the composition (X) and improve the heat resistance of the cured product. The content of the styrene-based elastomer (D) is more preferably equal to or greater than 10 parts by mass and equal to or less than 80 parts by mass, and even more preferably equal to or greater than 30 parts by mass and equal to or less than 60 parts by mass.

If the styrene-based elastomer (D) contains a styrene-hydrogenated diene copolymer (D1), the content of the styrene-hydrogenated diene copolymer (D1) is preferably equal to or greater than 5 parts by mass and equal to or less than 100 parts by mass, more preferably equal to or greater than 10 parts by mass and equal to or less than 80 parts by mass or less, and even more preferably equal to or greater than 30 parts by mass and equal to or less than 60 parts by mass, with respect to 100 parts by mass in total of the copolymer (A) and the compound (B).

The fibrous filler (E) may increase the plasticity and strength of the resin sheet made of the composition (X) as described above.

The fibrous filler (E) preferably has a fiber diameter Lc equal to or less than 10 μm. Also, the fibrous filler (E) preferably has a fiber length L1 equal to or less than 1 mm. The ratio of the fiber length L1 to the fiber diameter Lc is preferably equal to or greater than 10 and equal to or less than 10000.

Setting the fiber diameter Lc of the fibrous filler (E) at 10 μm or less makes it easier for the fibrous filler (E) to effectively increase the flexibility and tear strength of the resin film, and therefore, may reduce the chances of the content of the fibrous filler (E) in the composition (X) being excessively high. It is also preferable that the fibrous filler (E) have a fiber diameter Lc equal to or greater than 0.01 μm. This also makes it easier for the fibrous filler (E) to effectively increase the flexibility and tear strength of the resin film. The fibrous filler (E) more preferably has a fiber diameter Lc equal to or less than 8 μm, and even more preferably has a fiber diameter Lc equal to or less than 5 μm. Meanwhile, the fibrous filler (E) more preferably has a fiber diameter Lc equal to or greater than 0.05 μm, and even more preferably has a fiber diameter Lc equal to or greater than 0.1 μm.

Setting the fiber length L1 of the fibrous filler (E) at 1 mm or less reduces the chances of the composition (X) coming to have an excessively high viscosity when the composition (X) is prepared as a resin varnish, because the composition (X) contains a solvent. Therefore, the composition (X) tends to have sufficient flowability and may be easily formed into a sheet shape. Meanwhile, the fibrous filler (E) preferably has a fiber length L1 equal to or greater than 0.001 mm. This makes it easier for the fibrous filler (E) to effectively increase the flexibility and tear strength of the resin film. The fibrous filler (E) more preferably has a fiber length L1 equal to or less than 0.5 mm, and even more preferably has a fiber length L1 equal to or less than 0.3 mm Meanwhile, the fibrous filler (E) more preferably has a fiber length L1 equal to or greater than 0.001 mm, and even more preferably has a fiber length L1 equal to or greater than 0.02 mm.

Also, setting the ratio of the fiber length L1 to the fiber diameter Lc at a value equal to or greater than 10 and equal to or less than 10000 allows the fibrous filler (E) to increase the flexibility and tear strength of the resin film particularly significantly. This value is more preferably equal to or greater than 20 and equal to or less than 5000, even more preferably equal to or greater than 40 and equal to or less than 500, and particularly preferably equal to or greater than 40 and equal to or less than 100.

The fiber diameter Lc and the fiber length L1 may be measured by the following method. After the fiber diameters and fiber lengths of 50 fibers have been measured by observation through an electron microscope, their averages are calculated as the fiber diameter Lc and the fiber length L1, respectively.

The material for the fibrous filler (E) is not limited to any particular one. The fibrous filler (E) may contain at least one of a fibrous filler (E1) having an organic polymer or a fibrous filler (E2) containing an inorganic material. The organic polymer included in the fibrous filler (E1) may contain at least one selected from the group consisting of, for example, polyester and polyolefin. Specific examples of the fibrous filler containing polyester include Nano Frontier manufactured by Teijin Limited. Specific examples of the fibrous filler containing polyolefin include AIRYMO manufactured by UBE EXSYMO Co., Ltd. The fibrous filler (E2) containing an inorganic material may contain, for example, glass fiber.

The fibrous filler (E) preferably includes a fibrous filler (E1) having an organic polymer. In that case, the fibrous filler (E1) makes it easier to increase the plasticity of the cured product. In addition, it is particularly preferable that the organic polymer included in the fibrous filler (E1) contain polyolefin. This reduces the chances of the fibrous filler (E1) increasing the relative dielectric constant and the dielectric loss tangent of the cured product, thus making it easier to lower the dielectric constant and dielectric loss tangent of the cured product.

The proportion of the fibrous filler (E) in the composition (X) is preferably equal to or greater than 0.1 parts by mass and equal to or less than 30 parts by mass or less with respect to 100 parts by mass in total of the copolymer (A), the compound (B), the inorganic filler (C), and the styrene-based elastomer (D). Setting this proportion at 0.1 part by mass or more allows the fibrous filler (E) to increase the flexibility and tear strength of the resin film particularly significantly. Setting this proportion at 30 parts by mass or less enables lowering the viscosity of the composition (X) prepared as a resin varnish. This proportion is more preferably equal to or greater than 0.5 parts by mass and equal to or less than 25 parts by mass and even more preferably equal to or greater than 1.0 part by mass and equal to or less than 20 parts by mass.

The composition (X) preferably further contains an organic compound (F) having a polymerizable unsaturated bond (hereinafter simply referred to as an “organic compound (F)”) besides the copolymer (A) and the compound (B).

A polymerizable unsaturated group included in the organic compound (F) includes at least one group selected from the group consisting of a vinyl group, an allyl group, a methacrylic group, a styryl group, a meth(acrylic) group, and a maleimide group. If the composition (X) contains an organic compound (F), the physical properties of the composition (X) and a cured product thereof are controllable by selecting appropriate components included in the organic compound (F). For example, if the organic compound (F) contains a monofunctional compound having a single polymerizable unsaturated bond, then the monofunctional compound may reduce the melt viscosity of the composition (X) to improve the moldability. On the other hand, if the organic compound (F) contains a polyfunctional compound having a plurality of polymerizable unsaturated bonds, then the polyfunctional compound may increase the crosslink density of the cured product. Thus, the polyfunctional compound contributes to increasing the tenacity, the glass transition temperature, and therefore, the heat resistance of the cured product, decreasing the coefficient of linear expansion thereof, and increasing the degree of adhesiveness thereof. If the organic compound (F) contains a polyfunctional compound, then the polyfunctional compound preferably contains at least one compound selected from the group consisting of divinylbenzene, trivinylcyclohexane, triallyl isocyanurate (TAIC), dicyclopentadiene dimethanol dimethacrylate, and nonanediol dimethacrylate. This may improve the flame retardance of the cured product of the composition (X). It is also preferable that the polyfunctional compound contain bismaleimide. This may improve the flame retardance of the cured product of the composition (X) particularly significantly. The bismaleimide includes at least one compound selected from the group consisting of 4,4′-diphenylmethane bismaleimide, m-phenylene bismaleimide, bisphenol A diphenyl ether bismaleimide, 3,3′-dimethyl-5,5′-diethyl-4,4′-diphenylmethane bismaleimide, 4-methyl-1,3-phenylene bismaleimide, and 1,6-bismaleimide-(2,2,4-trimethyl) hexane. Specific examples of the bismaleimide include BMI-689 and BMI-3000, which are the names of products manufactured by DESIGNER MOLECULES.

If the composition (X) contains the organic compound (F), then the content of the organic compound (F) is preferably equal to or greater than 5 parts by mass and equal to or less than 50 parts by mass with respect to 100 parts by mass in total of the copolymer (A) and the compound (B). Setting the content of the organic compound (F) at 5 parts by mass or more contributes to improving the heat resistance of the cured product of the composition (X). Setting the content of the organic compound (F) at 50 parts by mass or less not only enables lowering the dielectric constant and dielectric loss tangent of the cured product of the composition (X) but also reduces the chances of causing tackiness.

Optionally, the composition (X) may contain a thermo-radical polymerization initiator. The thermo-radical polymerization initiator may promote the curing reaction of the composition (X) when the composition (X) is heated. Note that if the composition (X) contains a component that readily produces an activate species when heated, then the composition (X) may contain no thermo-radical polymerization initiators.

The thermo-radical polymerization initiator preferably contains a peroxide (G). That is to say, the composition (X) preferably contains a peroxide (G). This may promote the curing reaction of the composition (X) particularly significantly, shorten the time it takes to have the composition (X) cured, and contribute to improving the physical properties of the cured product by, for example, reducing the coefficient of linear expansion, increasing the glass transition temperature, and improving the solder heat resistance. The peroxide (G) contains at least one component selected from the group consisting of, for example, α,α′-bis(t-butylperoxy-m-isopropyl) benzene, 2,5-dimethyl-2,5-di(t-butylperoxy)-3-hexine, benzoyl peroxide, 3,3′,5,5′-tetramethyl-1,4-diphenoquinone, chloranil, 2,4,6-tri-t-butylphenoxyl, t-butylperoxy isopropyl monocarbonate, t-amylperoxy neodecanoate, t-amylperoxy pivalate, t-amylperoxy-2-ethyl hexanoate, t-amylperoxy normal octoate, t-amylperoxy acetate, t-amylperoxy isononanoate, t-amylperoxy benzoate, t-amylperoxyisopropyl carbonate, di-t-amyl peroxide, 1,1-di (t-amylperoxy) cyclohexane, and azobisisobutyronitrile.

The content of the thermo-radical polymerization initiator may be, but does not have to be, equal to or greater than 0.1 parts by mass and equal to or less than 5 parts by mass with respect to 100 parts by mass of the entire radical polymerizable components in the composition (X), for example. As used herein, the “radical polymerizable component” refers to a component that produces radical polymerization reaction while the composition (X) is heated and cured. The radical polymerizable component includes the copolymer (A) and the compound (B). If the composition (X) contains the organic compound (F), the radical polymerizable component further includes the organic compound (F) as well.

The composition (X) may further contain a flame retardant (H). The flame retardant (H) preferably includes a flame retardant (H1) containing at least one of bromine or phosphorus. This may improve the flame retardance while decreasing the dielectric constant of the cured product of the composition (X). The flame retardant (H1) may include at least one of a bromine-containing flame retardant (H11) or a phosphorus-containing flame retardant (H12).

The flame retardant (H11) preferably contains, for example, an aromatic bromine compound. The flame retardant (H11) preferably contains at least one selected from the group consisting of decabromodiphenylethane, 4,4-dibromobiphenyl, and ethylenebistetrabromo-phthalimide.

If the composition (X) contains the flame retardant (H11), the content of bromine in the flame retardant (H11) with respect to the composition (X) is preferably equal to or greater than 8% by mass and equal to or less than 20% by mass. This improves the flame retardance of the cured product of the composition (X) and reduces the chances of bromine being dissociated from the cured product when the cured product is heated.

The flame retardant (H12) preferably contains, for example, at least one of an incompatible phosphorus compound or a compatible phosphorus compound.

The flame retardant (H12) preferably contains, as the incompatible phosphorus compound, a phosphine oxide compound having two or more diphenylphosphine oxide groups per molecule, for example. The melting point of this phosphine oxide compound is preferably equal to or higher than 280° C. The phosphine oxide compound preferably includes a compound which is one or more linking groups selected from the group consisting of a phenylene group, a xylylene group, a biphenylene group, a naphthylene group, a methylene group, and an ethylene group, and which has a structure in which two or more diphenylphosphine oxide groups are linked.

The flame retardant (H12) preferably contains, as the compatible phosphorus compound, at least one selected from the group consisting of, for example, a phosphoric acid ester compound, a phosphazene compound, a phosphorous acid ester compound, and a phosphine compound.

If the composition (X) contains the flame retardant (H12), the content of phosphorus in the flame retardant (H12) with respect to the composition (X) is preferably equal to or greater than 1.8% by mass and equal to or less than 5.2% by mass. This improves the flame retardance of the cured product of the composition (X) and reduces the chances of phosphorus being dissociated from the cured product when the cured product is heated.

The composition (X) may contain an organic radical compound (I). The organic radical compound (I) facilitates improving the storage stability of each of the uncured product of the composition (X) and the semi-cured product of the composition (X) and reduces the chances of causing an increase in the coefficient of linear expansion of the cured product and a decrease in the glass transition temperature thereof, which are normally involved when the storage stability is improved.

The organic radical compound (I) preferably includes an organic nitroxide radical compound (I1). This makes it particularly easy for the organic radical compound (I) to achieve the above-described advantage.

The organic nitroxide radical compound (I1) contains, for example, at least one compound selected from the group consisting of a compound expressed by the following Formula (7), a compound expressed by the following Formula (8), a compound expressed by the following Formula (9), a compound expressed by the following Formula (10), and a compound expressed by the following Formula (11). Note that the compound that may be contained in the organic nitroxide radical compound (I1) is not limited to these. In Formula (10), n is a number of 1 to 18. In Formula (11), R is either hydrogen or a hydroxyl group.

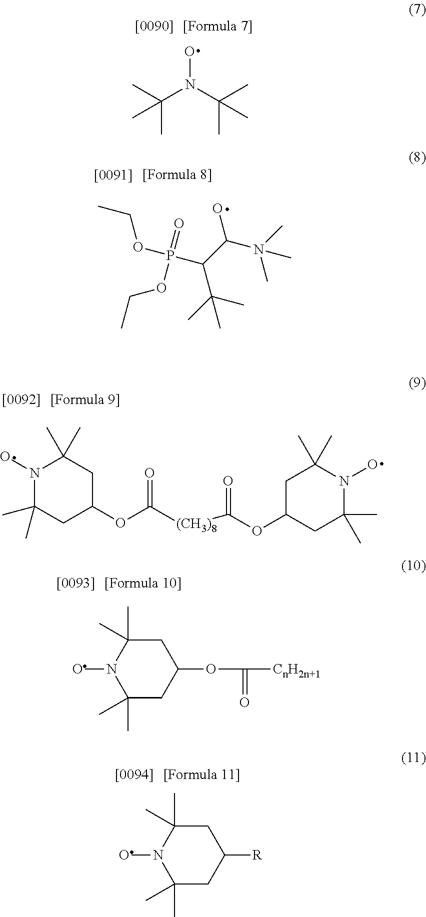

The organic nitroxide radical compound (I1) preferably contains at least one component selected from the group consisting of 2,2,6,6-tetramethylpiperidine 1-oxyl and its derivatives. For example, the organic nitroxide radical compound (I1) preferably contains at least one component selected from the group consisting of the compound expressed by Formula (9), the compound expressed by Formula (10), and the compound expressed by Formula (11).

The organic nitroxide radical compound (I1) preferably contains the compound expressed by Formula (11), in particular. It is particularly preferable that R in Formula (11) be hydrogen. This makes it particularly easy to improve the dielectric properties of the cured product.

The content of the organic radical compound (I) with respect to the radical polymerizable component in the composition (X) is preferably equal to or greater than 0.01% by mass and equal to or less than 5.0% by mass. Setting this content at 0.05% by mass or more may improve the moldability. Setting this content at 5.0% by mass or less may reduce the coefficient of linear expansion of the cured product. The content of the organic radical compound (I) is more preferably equal to or greater than 0.05% by mass and equal to or less than 4.0% by mass, and even more preferably equal to or greater than 0.05% by mass and equal to or less than 3.0% by mass.

The composition (X) may contain additional components other than the above-described ones. For example, the composition (X) may contain at least one component selected from the group consisting of a defoaming agent such as a silicone defoaming agent or an acrylic acid ester defoaming agent, a heat stabilizer, an antistatic agent, an ultraviolet absorber, a dye, a pigment, a lubricant, and a dispersant such as a wetting dispersant.

The composition (X) may contain a solvent. That is to say, the composition (X) may contain a solvent and thereby be prepared as a resin varnish. This makes it easier to form the composition (X) into a sheet shape. The solvent preferably contains at least one component selected from the group consisting of an aliphatic hydrocarbon solvent, an aromatic hydrocarbon dissolve, and a ketone solvent.

If the composition (X) contains a solvent, the content of the solvent is preferably adjusted such that the composition (X) has a solid content concentration equal to or greater than 20% by mass and equal to or less than 90% by mass. As used herein, the “solid content” refers to a component included in the composition (X) which forms a cured product. That is to say, the solid content refers to the component of the composition (X) other than its component that vaporizes while the composition (X) is being cured to turn into a cured product. Setting the solid content concentration at 90% by mass or less makes the composition (X) smoothly flowable, thus making it easier to form the composition (X) into a sheet shape. Meanwhile, setting the solid content concentration at 20% by mass or more makes it easier to form a resin sheet by drying, and thereby vaporizing the solvent from, the composition (X) that has been formed into a sheet shape. The solid content concentration is more preferably equal to or greater than 25% by mass and equal to or less than 85% by mass, and even more preferably equal to or greater than 30% by mass and equal to or less than 80% by mass.

If the composition (X) has been prepared as a resin varnish, the viscosity of the composition (X) at 30° C. is preferably equal to or greater than 100 mPa·s and equal to or less than 100000 mPa·s. This makes it easier to form the composition (X) into a sheet shape. The viscosity is more preferably equal to or greater than 300 mPa·s and equal to or less than 50000 mPa·s and even more preferably equal to or greater than 1000 mPa·s and equal to or less than 20000 mPa·s.

Note that a method for measuring the viscosity of the composition (X) at 30° C. will be described in further detail later in the “Examples” section.

The cured product of the composition (X) preferably has a relative dielectric constant equal to or less than 4.0 at a test frequency of 10 GHz. This makes it easier to lower the dielectric constant of an insulating layer made of the composition (X). The relative dielectric constant is more preferably equal to or greater than 2.0 and equal to or less than 4.0, and even more preferably equal to or greater than 2.1 and equal to or less than 3.5. The cured product of the composition (X) preferably has a dielectric loss tangent equal to or less than 0.005 at a test frequency of 10 GHz. This makes it easier to lower the dielectric loss tangent of an insulating layer made of the composition (X). The dielectric loss tangent is more preferably equal to or less than 0.004 and even more preferably equal to or less than 0.003. The cured product is allowed to have such a low dielectric constant and a low dielectric loss tangent easily by the composition (X) according to this embodiment. Note that a method for measuring the relative dielectric constant and dielectric loss tangent will be described in detail later in the “Examples” section.

A resin sheet, a sheet of metal foil with resin, a metal-clad laminate, and a printed wiring board may be each manufactured by using the composition (X).

The resin sheet includes an uncured product or semi-cured product of the composition (X). The resin sheet may be used as a material for making a laminate and a printed wiring board. That is to say, the resin sheet may be used to make a laminate with an insulating layer including a cured product of the resin sheet (i.e., an insulating layer including a cured product of the composition (X)) and a printed wiring board with an insulating layer including a cured product of the resin sheet (i.e., an insulating layer including a cured product of the composition (X)).

The resin sheet preferably includes no fibrous base member as in the case of a prepreg. To make a resin sheet, the composition (X) may be formed into a sheet shape by an application method, for example, and then heated to be dried or semi-cured. In this manner, a resin sheet including an uncured product or semi-cured product of the composition (X) is obtained. The heating temperature only needs to be high enough to dry the solvent included in the composition (X) and thereby semi-cure the resin component, and may be, for example, equal to or higher than 100° C. and equal to or lower than 160° C., and the heating duration may be, for example, equal to or longer than 5 minutes and equal to or shorter than 10 minutes.

The resin sheet preferably has a tear strength equal to or greater than 0.2 N. This particularly significantly reduces the chances of causing damage (such as a tear) to the resin sheet. The tear strength is more preferably equal to or greater than 0.25 N and even more preferably equal to or greater than 0.3 N. Meanwhile, the tear strength may be equal to or less than 1 N, for example. Making the resin sheet of the composition (X) according to this embodiment increases the chances of achieving a tear strength at this level. Note that a method for measuring the tear strength will be described in detail later in the “Examples” section.

Heating and curing the resin sheet allows an insulating layer including a cured product of the composition (X) to be formed. The heating temperature may be, for example, equal to or higher than 160° C. and equal to or lower than 200° C. and is preferably equal to or higher than 180° C. and equal to or lower than 200° C., and the heating duration may be, for example, equal to or longer than 30 minutes and equal to or shorter than 120 minutes and is preferably equal to or longer than 60 minutes and equal to or shorter than 120 minutes.

The resin sheet may be used as a bonding sheet for bonding a plurality of layers together. Specifically, the composition (X) may be applied onto a supporting film, for example, and formed into a sheet shape, and then dried or semi-cured, thus making a resin sheet. This resin sheet is attached onto a substrate and then the supporting film is peeled from the resin sheet. Subsequently, another substrate is attached onto the resin sheet. That is to say, the resin sheet is interposed between the two substrates. Subsequently, the resin sheet is heated to be cured, thereby forming an insulating layer. This allows the two substrates to be bonded together via this insulating layer.

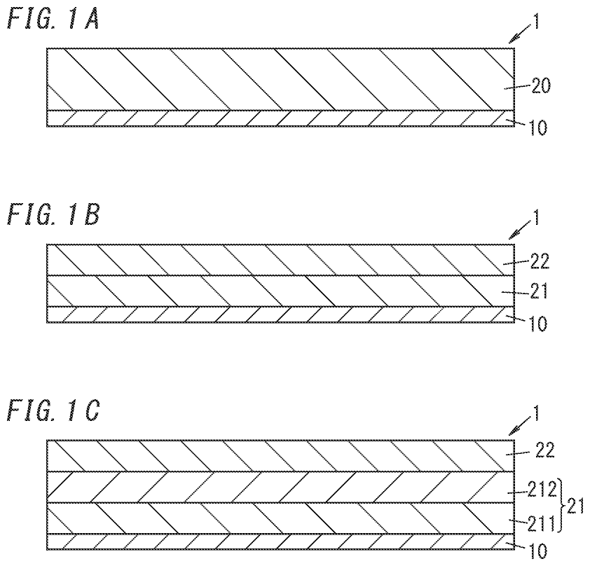

The sheet of metal foil 1 with resin includes a sheet of metal foil 10 and a resin layer 20 laid on top of the sheet of metal foil 10 as shown in FIG. 1A. The resin layer 20 includes an uncured product or semi-cured product of the composition (X). That is to say, the resin layer 20 is formed out of a resin sheet made of the composition (X). In this case, the composition (X) is formed, by an application method, for example, into a sheet shape on the sheet of metal foil 10 and then heated to be dried or semi-cured. In this manner, the resin layer 20 may be formed. In this case, the condition for heating the composition (X) preferably includes a heating temperature equal to or higher than 100° C. and equal to or lower than 160° C. and a heating duration equal to or longer than 5 minutes and equal to or shorter than 10 minutes.

If a metal-clad laminate or a printed wiring board is formed based on the sheet of metal foil 1 with resin, then an insulating layer is formed out of the resin layer 20. This makes it easier to lower the dielectric constant and dielectric loss tangent of the insulating layer.

The sheet of metal foil 10 may be a sheet of copper foil, for example. The sheet of metal foil 10 may have a thickness equal to or greater than 2 μm and equal to or less than 105 μm, for example, and preferably has a thickness equal to or greater than 5 μm and equal to or less than 35 μm. The sheet of metal foil 10 may be, for example, a sheet of copper foil having a thickness of 2 μm with a copper carrier having a thickness of 18 μm.

Although the resin layer 20 shown in FIG. 1A is a single layer including an uncured product or semi-cured product of the composition (X), the resin layer 20 may include a plurality of layers with mutually different compositions. In that case, the plurality of layers may include a layer including either an uncured product or semi-cured product of the composition (X) and a layer including neither an uncured product nor semi-cured product of the composition (X).

The sheet of metal foil 1 with resin may include: the sheet of metal foil 10; a first resin layer 21 stacked on the sheet of metal foil 10; and a second resin layer 22 stacked on the first resin layer 21 as shown in FIG. 1B. The first resin layer 21 contains at least one component selected from the group consisting of a liquid crystal polymer resin, a polyimide resin, a polyamide imide resin, a fluorocarbon resin, and a polyphenylene ether resin. The second resin layer 21 includes an uncured product or semi-cured product of the composition (X). That is to say, the second resin layer is formed out of a resin sheet made of the composition (X). In this case, an insulating layer consisting of the first resin layer 21 and the second resin layer 22 may be formed. This insulating layer includes a cured product of the second resin layer 22, thus making it easier to lower the dielectric constant and dielectric loss tangent of the insulating layer. In addition, the insulating layer includes either the first resin layer 21 or a cured product thereof, thus making it easier to impart flexibility to the insulating layer. The flexibility imparted to the insulating layer by either the first resin layer 21 or a cured product thereof is unlikely to be inhibited by the cured product of the second resin layer 22. That is why the sheet of metal foil 1 with resin is suitable to making a flexible metal-clad laminate or a flexible printed wiring board.

The first resin layer 21 may have a thickness equal to or greater than 1 μm and equal to or less than 50 μm, for example. The second resin layer 22 may have a thickness equal to or greater than 5 μm and equal to or less than 200 μm, and preferably has a thickness equal to or greater than 10 μm and equal to or less than 150 μm, for example.

The first resin layer 21 preferably includes at least one component selected from the group consisting of, for example, a liquid crystal polymer resin, a polyimide resin, a polyamide imide resin, a fluorocarbon resin, and a polyphenylene ether resin. That is to say, the first resin layer 21 is preferably made from, for example, a resin solution or sheet material including at least one component selected from the group consisting of, for example, a liquid crystal polymer resin, a polyimide resin, a polyamide imide resin, a fluorocarbon resin, and a polyphenylene ether resin. Optionally, the sheet material to make the first resin layer 21 may include a base member such as a piece of glass cloth therein and may be reinforced with the base member. The sheet material may be a prepreg, for example. The first resin layer 21 may be formed by, for example, either applying a resin solution onto the sheet of metal foil 10 and drying the resin solution or laying a sheet material on top of the sheet of metal foil 10 and then heat-pressing the sheet material.

The liquid crystal polymer resin may contain at least one component selected from the group consisting of: polycondensates of ethylene terephthalate and para-hydroxybenzoic acid; polycondensates of a phenol, phthalic acid, and para-hydroxybenzoic acid; and polycondensates of 2,6-hydroxynaphthoic acid and para-hydroxybenzoic acid. If the first resin layer 21 contains the liquid crystal polymer resin, the first resin layer 21 may be formed by for example, forming the liquid crystal polymer resin into a sheet material and then laying the sheet material on top of the sheet of metal foil.

The polyimide resin may be prepared in the following manner, for example. First, polyamide acid is produced by polycondensation of tetracarboxylic dianhydride and a diamine component. The tetracarboxylic dianhydride preferably contains 3,3′,4,4′-diphenyl sulfone tetracarboxylic dianhydride. The diamine component preferably includes a component selected from the group consisting of 2,2-bis [4-(4-aminophenoxy) phenyl] propane, 4,4′-diaminodiphenyl ether, and bis [4-(4-aminophenoxy) phenyl] sulfone. Subsequently, the polyamide acid is heated in a solvent. This causes the polyamide acid to turn into an imide through cyclization reaction, thus producing a polyimide resin. The solvent may contain at least one component selected from the group consisting of N-methyl-2-pyrrolidone, methyl ethyl ketone, toluene, dimethyl acetamide, dimethylformamide, and methoxy propanol. The heating temperature may be, for example, equal to or higher than 60° C. and equal to or lower than 250° C. and is preferably equal to or higher than 100° C. and equal to or lower than 200° C. The heating duration may be, for example, equal to or longer than 0.5 hours and equal to or shorter than 50 hours. If the first resin layer 21 contains a polyimide resin, a resin solution containing the polyimide resin may be applied onto the sheet of metal foil 10 and then heated and dried, for example. In this manner, the first resin layer 21 may be formed.

The polyamide imide resin may be prepared in the following manner, for example. First, trimellitic anhydride, 4,4′-diisocyanato-3,3′-dimethylbiphenyl, tolylene-2,4-diisocyanate, diazabicycloundecene, and N,N-dimethylacetamide are mixed together to prepare a mixture. The mixture is then heated and thereby the respective components thereof are allowed to react to each other to obtain a mixture containing polyamide imide. Subsequently, the mixture is cooled. Then, bismaleimide is added to this mixture. In this manner, a resin solution containing polyamide imide is obtained. If the first resin layer 21 contains the polyamide imide resin, a resin solution containing the polyamide imide resin may be applied onto the sheet of metal foil 10 and then heated and dried, for example. In this manner, the first resin layer 21 may be formed.

The fluorocarbon resin may include polytetrafluoroethylene, for example.

The polyphenylene ether resin preferably has a substituent group having a carbon-carbon double bond at a terminal. If the first resin layer 21 contains the polyphenylene ether resin, the first resin layer 21 preferably further includes a crosslink agent having a carbon-carbon double bond. The crosslink agent may contain at least one component selected from the group consisting of divinylbenzene, polybutadiene, alkyl (meth)acrylate, tricyclodecanol (meth)acrylate, fluorene (meth)acrylate, isocyanurate (meth)acrylate, and trimethylolpropane (meth)acrylate. The content of the polyphenylene ether resin to the total of the polyphenylene ether resin and the crosslink agent may be, for example, equal to or greater than 65% by mass and equal to or less than 95% by mass. If the first resin layer 21 contains the polyphenylene ether resin, the first resin layer 21 may be formed by, for example, applying a resin solution containing the polyphenylene ether resin and the crosslink agent onto the sheet of metal foil 10 and then thermally curing the resin solution.

The first resin layer 21 may be a single layer as shown in FIG. 1B. Alternatively, the first resin layer 21 may be made up of a plurality of layers. For example, the first resin layer 21 may include a first layer 211 and a second layer 212 having mutually different compositions as shown in FIG. 1C.

The first layer 211 and the second layer 212 may each contain at least one component selected from the group consisting of, for example, a liquid crystal polymer resin, a polyimide resin, a polyamide imide resin, a fluorocarbon resin, and a polyphenylene ether resin and may have mutually different compositions.

The first layer 211 and the second layer 212 may be obtained by, for example, forming the first layer 211 and the second layer 212 in this order onto the sheet of metal foil 10 in the same way as described above. Specifically, first, a resin solution containing the component of the first layer 211 is applied onto the sheet of metal foil 10 and then dried to form the first layer 211. Next, a resin solution containing the component of the second layer 212 is applied onto the first layer 211 and then dried to form the second layer 212. Alternatively, the first layer 211 and the second layer 212 may also be formed out of a sheet material, instead of the resin solution.

The second resin layer 22 preferably includes an uncured product or semi-cured product of the composition (X). Thus, the second resin layer 22 may be formed by, for example, applying the composition (X) onto the first resin layer 21 and then drying or semi-curing the composition (X). In this case, the condition for heating the composition (X) preferably includes a heating temperature equal to or higher than 100° C. and equal to or lower than 160° C. and a heating duration equal to or longer than 5 minutes and equal to or shorter than 10 minutes, for example. Alternatively, the second resin layer 22 may also be formed by, for example, laying a resin sheet including an uncured or semi-cured product of the composition (X) onto the first resin layer 21.

In the sheet of metal foil 1 with resin shown in FIG. 1C, the first resin layer 21 includes two layers (namely, the first layer 211 and the second layer 212). Optionally, the first resin layer 21 may include three or more layers. For example, the first resin layer 21 may include a first layer, a second layer, and a third layer, which may be stacked one on top of another in this order. In that case, the first and second layers have mutually different compositions and the second and third layers have mutually different compositions. Meanwhile, the first and third layers may have mutually different compositions or the same composition, whichever is appropriate.

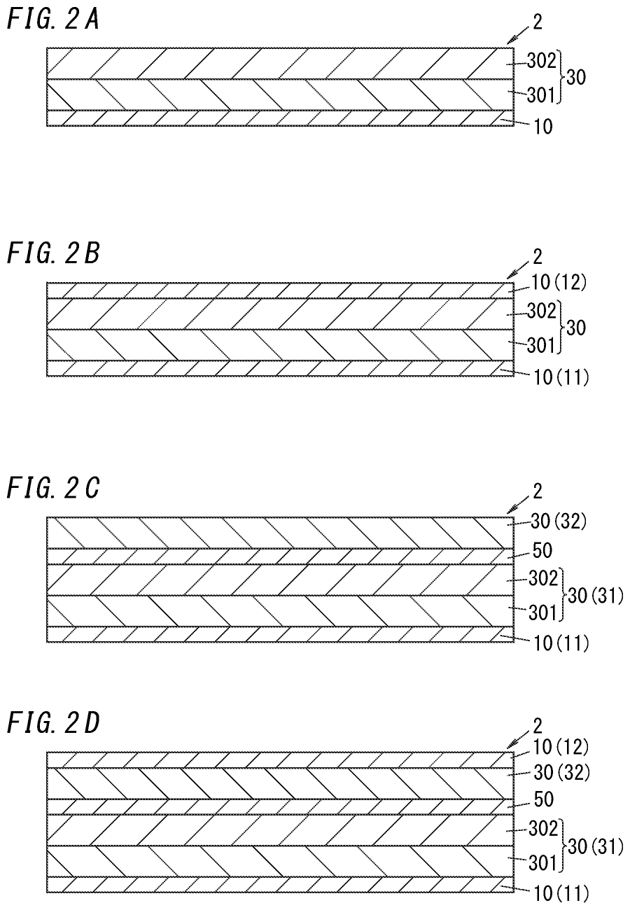

Next, the metal-clad laminate 2 will be described. As shown in FIGS. 2A-2D, the metal-clad laminate 2 includes an insulating layer 30 and the sheet of metal foil 10.

The metal-clad laminate 2 includes the sheet of metal foil 10 as its outermost layer. The metal-clad laminate 2 may include either a single sheet of metal foil 10 or multiple sheets of metal foil 10, whichever is appropriate. If the metal-clad laminate 2 includes multiple sheets of metal foil 10, then the metal-clad laminate 2 includes one of the multiple sheets of metal foil 10 as its outermost layer.

The insulating layer 30 includes a cured product of the composition (X). The insulating layer 30 may further contain at least one component selected from the group consisting of a liquid crystal polymer resin, a polyimide resin, a polyamide imide resin, a fluorocarbon resin, and a polyphenylene ether resin.

The metal-clad laminate 2 may include only one insulating layer 30 as shown in FIGS. 2A and 2B or include two or more insulating layers 30 as shown in FIGS. 2C and 2D, whichever is appropriate.

If the metal-clad laminate 2 includes only one insulating layer 30, then the insulating layer 30 either consists of only a layer including a cured product of the composition (X), for example, or includes a layer including a cured product of the composition (X) and another layer. For example, the insulating layer 30 may include a layer including a cured product of the composition (X) and a layer including at least one component selected from the group consisting of a liquid crystal polymer resin, a polyimide resin, a polyamide imide resin, a fluorocarbon resin, and a polyphenylene ether resin. In that case, the insulating layer 30 may include a first layer 301 and a second layer 302 laid on top of the first layer 301. The first layer 301 includes at least one component selected from the group consisting of a liquid crystal polymer resin, a polyimide resin, a polyamide imide resin, a fluorocarbon resin, and a polyphenylene ether resin. The second layer 302 includes a cured product of the composition (X). The first layer 301 may have a thickness equal to or greater than 1 μm and equal to or less than 50 μm, for example. The second layer 302 may have a thickness equal to or greater than 5 μm and equal to or less than 50 μm, for example.

If the metal-clad laminate 2 includes two or more insulating layers 30, then the two or more insulating layers 30 may include an insulating layer 30 including a cured product of the composition (X) and preferably includes an insulating layer 30 including at least one component selected from the group consisting of a liquid crystal polymer resin, a polyimide resin, a polyamide imide resin, a fluorocarbon resin, and a polyphenylene ether resin. Alternatively, the two or more insulating layers 30 also preferably include an insulating layer 30 including a cured product of the composition (X) and at least one component selected from the group consisting of a liquid crystal polymer resin, a polyimide resin, a polyamide imide resin, a fluorocarbon resin, and a polyphenylene ether resin. In that case, at least one of the two or more insulating layers 30 may be a layer including the first layer 301 and the second layer 302 laid on top of the first layer 301. Each of the two or more insulating layers 30 more preferably includes at least one component selected from the group consisting of a liquid crystal polymer resin, a polyimide resin, a polyamide imide resin, a fluorocarbon resin, and a polyphenylene ether resin.

The material and thickness of the sheet of metal foil 10 may be the same as those of the sheet of metal foil 10 included in the sheet of metal foil with resin described above.

Forming the metal-clad laminate 2 including the insulating layer 30 that includes a cured product of the composition (X) enables lowering the dielectric constant and dielectric loss tangent of the insulating layer 30.

Forming the metal-clad laminate 2 including the insulating layer 30 that includes the first layer 301 and the second layer 302 enables further lowering the dielectric constant and dielectric loss tangent of the insulating layer 30.

The metal-clad laminates 2 shown in FIGS. 2A-2D will be described in further detail.

The metal-clad laminate 2 shown in FIG. 2A includes the sheet of metal foil 10, the first layer 301, and the second layer 302, which are stacked one on top of another in this order. The metal-clad laminate 2 shown in FIG. 2A may be formed by, for example, stacking the sheet of metal foil 10, a sheet material containing the component of the first layer 301, and a resin sheet including an uncured product or semi-cured product of the composition (X) in this order one on top of another and then subjecting the stack to heat pressing.

Alternatively, in the metal-clad laminate 2 shown in FIG. 2A, the sheet of metal foil 10, the second layer 302, and the first layer 301 may be stacked one on top of another in this order. That is to say, the first layer 301 and the second layer 302 may be stacked in reverse order from the example illustrated in FIG. 1A. Furthermore, the first layer 301 may include two or more layers. In that case, two layers that are directly in contact with each other in the first layer 301 have mutually different compositions. Meanwhile, two layers that are not directly in contact with each other in the first layer 301 may have either the same composition or mutually different compositions, whichever is appropriate.

The metal-clad laminate 2 shown in FIG. 2B includes a sheet of metal foil 10 (first sheet of metal foil 11), the insulating layer 30, and another sheet of metal foil 10 (second sheet of metal foil 12), which are stacked one on top of another in this order. That is to say, the metal-clad laminate 2 shown in FIG. 2B has the same configuration as the metal-clad laminate 2 shown in FIG. 2A except that the metal-clad laminate 2 shown in FIG. 2B further includes the second sheet of metal foil 12. The metal-clad laminate 2 shown in FIG. 2B may be formed by providing and stacking the first sheet of metal foil 11, a sheet material containing the component of the first layer 301, a sheet material containing the component of the second layer 302, and the second sheet of metal foil 12 one on top of another in this order and then heat-pressing these members together.

The metal-clad laminate 2 shown in FIG. 2C includes a sheet of metal foil 10 (as a first sheet of metal foil 11), an insulating layer 30 (as a first insulating layer 31), a conductor layer 50, and another insulating layer 30 (as a second insulating layer 32), which are stacked one on top of another in this order. The first insulating layer 31 includes the first layer 301 and the second layer 302. The first insulating layer 31 may have the same structure as the insulating layer 30 of the metal-clad laminate 2 shown in FIG. 2A. The second insulating layer 32 includes at least one component selected from the group consisting of a thermosetting resin composition, a liquid crystal polymer resin, a polyimide resin, a polyamide imide resin, a fluorocarbon resin, and a polyphenylene ether resin. The conductor layer 50 is implemented as, for example, a sheet of metal foil or conductor wiring. The metal-clad laminate 2 shown in FIG. 2C may be formed by, for example, providing and stacking the sheet of metal foil 10 (the first sheet of metal foil 11), a sheet material containing the component of the first layer 301, a sheet material containing the component of the second layer 302, the conductor layer 50, and a sheet material containing the component of the second insulating layer 32 one on top of another in this order and then heat-pressing these members together.

The metal-clad laminate 2 shown in FIG. 2D includes a sheet of metal foil 10 (first sheet of metal foil 11), the insulating layer 30 (first insulating layer 31), the conductor layer 50, the insulating layer 30 (second insulating layer 32), and another sheet of metal foil 10 (second sheet of metal foil 12), which are stacked one on top of another in this order. The first insulating layer 31 includes the first layer 301 and the second layer 302. That is to say, the metal-clad laminate 2 shown in FIG. 2D has the same configuration as the metal-clad laminate 2 shown in FIG. 2C except that the metal-clad laminate 2 shown in FIG. 2D further includes the second sheet of metal foil 12. The metal-clad laminate 2 shown in FIG. 2D may be formed by, for example, providing and stacking the first sheet of metal foil 11, a sheet material containing the component of the first layer 301, a sheet material containing the component of the second layer 302, the conductor layer 50, a sheet material containing the component of the second insulating layer, and the second sheet of metal foil 12 one on top of another in this order and then heat-pressing these members together. The conductor layer 50 is a sheet of metal foil.

Note that the specific examples shown in FIGS. 2A-2D are only exemplary structures for the metal-clad laminate 2 and should not be construed as limiting. For example, the metal-clad laminate 2 may include one or more sheets of metal foil 10, two or more conductor layers 50, and three or more insulating layers 30. The conductor layer 50 is interposed between two adjacent ones of the insulating layers 30. The sheet of metal foil 10 forms the outermost layer of the metal-clad laminate 2. At least one of the three or more insulating layers 30 includes a cured product of the composition (X). At least one of the three or more insulating layers 30 preferably contains at least one component selected from the group consisting of a liquid crystal polymer resin, a polyimide resin, a polyamide imide resin, a fluorocarbon resin, and a polyphenylene ether resin.

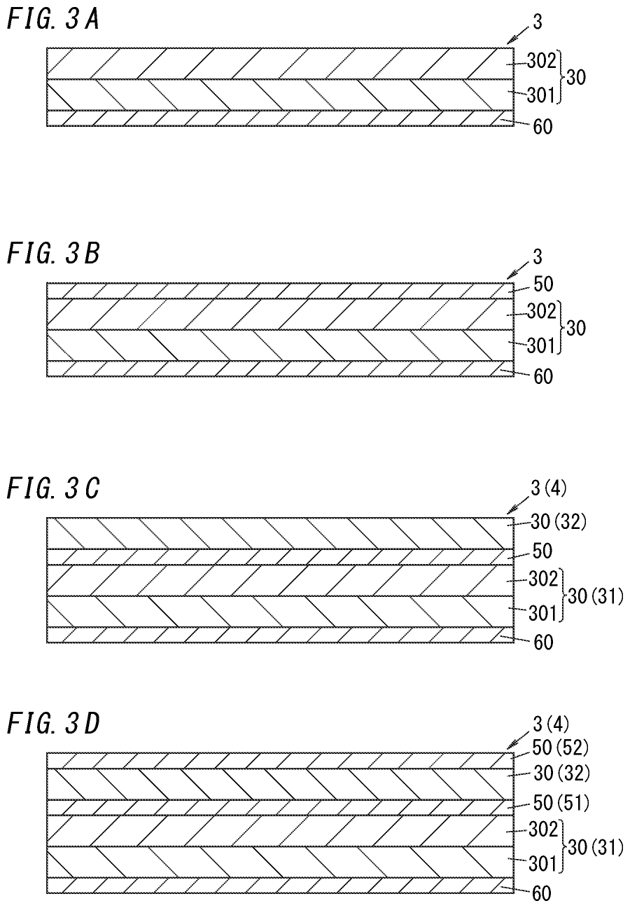

As shown in FIGS. 3A-3D, the printed wiring board 3 includes an insulating layer 30 and conductor wiring 60. The printed wiring board 3 includes the conductor wiring 60 as an outermost layer thereof. The insulating layer 30 contains a cured product of the composition (X). This enables lowering the dielectric constant and dielectric loss tangent of the insulating layer 30.

The printed wiring board 3 may include a single insulating layer 30 as shown in FIGS. 3A and 3B or may include a plurality of insulating layers 30 as shown in FIGS. 3C and 3D. If the printed wiring board 3 includes a plurality of insulating layers 30, at least one of the plurality of insulating layers 30 contains the composition (X). In addition, at least one of the insulating layers 30 preferably contains at least one component which is different from the composition (X) and selected from the group consisting of a liquid crystal polymer resin, a polyimide resin, a polyamide imide resin, a fluorocarbon resin, and a polyphenylene ether resin. In particular, each of the printed wiring boards 3 shown in FIGS. 3C and 3D includes one or more layers of conductor wiring 60 and two or more insulating layers 30, and therefore, is also a multilayer printed wiring board 4.

The insulating layer 30 may be either a single layer or include a plurality of layers, whichever is appropriate. The printed wiring boards 3 shown in FIGS. 3A-3D each include the insulating layer 30 consisting of a first layer 301 and a second layer 302 laid on top of the first layer 301. The insulating layer 30 has the same configuration as the insulating layer 30 of the metal-clad laminate 2 described above.

The printed wiring boards 3 shown in FIGS. 3A-3D will be described in further detail.

The printed wiring board 3 shown in FIG. 3A includes conductor wiring 60, a first layer 301, and a second layer 302, which are stacked one on top of another in this order. The printed wiring board 3 has the same configuration as the metal-clad laminate 2 shown in FIG. 2A, except that the printed wiring board 3 includes the conductor wiring 60 instead of the sheet of metal foil 10. The printed wiring board 3 may be fabricated by forming the conductor wiring 60 by, for example, removing (e.g., etching) excessive portions of the sheet of metal foil 10 of the metal-clad laminate 2 shown in FIG. 2A.

The printed wiring board 3 shown in FIG. 3B includes the conductor wiring 60, an insulating layer 30, and a conductor layer 50, which are stacked one on top of another in this order. The printed wiring board 3 has the same configuration as the metal-clad laminate 2 shown in FIG. 2B, except that the printed wiring board 3 includes the conductor wiring 60 instead of the first sheet of metal foil 11 and includes the conductor layer 50 (second conductor layer 52) instead of the second sheet of metal foil 12. Thus, the printed wiring board 3 may be fabricated by forming the conductor wiring 60 by, for example, removing (e.g., etching) excessive portions of the first sheet of metal foil 11 of the metal-clad laminate 2 shown in FIG. 2B and by applying a sheet of metal foil for the second conductor layer 52 instead of the second sheet of metal foil 12.

The printed wiring board 3 shown in FIG. 3C includes the conductor wiring 60, an insulating layer 30 (first insulating layer 31), the conductor layer 50, and another insulating layer 30 (second insulating layer 32), which are stacked one on top of another in this order. The printed wiring board 3 has the same configuration as the metal-clad laminate 2 shown in FIG. 2C, except that the printed wiring board 3 includes the conductor wiring 60 instead of the sheet of metal foil 10. The printed wiring board 3 may be fabricated by forming the conductor wiring 60 by, for example, removing (e.g., etching) excessive portions of the sheet of metal foil 10 of the metal-clad laminate 2 shown in FIG. 2C.

The printed wiring board 3 shown in FIG. 3D includes the conductor wiring 60, the insulating layer 30 (first insulating layer 31), a conductor layer 50 (first conductor layer 51), the insulating layer 30 (second insulating layer 32), and another conductor layer 50 (second conductor layer 52), which are stacked one on top of another in this order. The printed wiring board 3 has the same configuration as the metal-clad laminate 2 shown in FIG. 2D, except that the printed wiring board 3 includes the conductor wiring 60 instead of the first sheet of metal foil 11 and includes the conductor layer 50 (second conductor layer 52) instead of the second sheet of metal foil 12. The printed wiring board 2 may be fabricated by forming the conductor wiring 60 by, for example, removing (e.g., etching) excessive portions of the first sheet of metal foil 11 of the metal-clad laminate 2 shown in FIG. 2D and by applying a sheet of metal foil for the second conductor layer 52 instead of the second sheet of metal foil 12.

The printed wiring boards 3 shown in FIGS. 3C and 3D each include two insulating layers 30. However, this is only an example and should not be construed as limiting. Alternatively, the printed wiring board 3 may include three or more insulating layers 30, for example.

### EXAMPLES

Next, more specific examples of this embodiment will be presented. Note that the examples to be described below are only examples of this embodiment and should not be construed as limiting.

1. Preparation of Composition

A composition was prepared by mixing the components shown in the “Composition” column of Tables 1 and 2. The following are the details of the components shown in the “Composition” column of Tables 1 and 2:
Copolymer 1: ethylene-propylene-diene copolymer having a Mooney viscosity (ML (1+4) 100° C.) of 15, an ethylene content of 72%, and a diene content of 3.6%; product number X-3012P manufactured by Mitsui Chemicals, Inc.;
Copolymer 2: ethylene-propylene-diene copolymer having a Mooney viscosity (ML (1+4) 100° C.) of 20, an ethylene content of 77%, and a diene content of 10.4%; product number K-9720 manufactured by Mitsui Chemicals, Inc.;
Modified PPE1: terminal-modified polyphenylene ether compound; product number OPE-2St 1200 manufactured by Mitsubishi Gas Chemical Company, Inc.;
Modified PPE2: terminal-modified polyphenylene ether compound; product number OPE-2St 2400 manufactured by Mitsubishi Gas Chemical Company, Inc.;
Organic compound 1 having a polymerizable unsaturated group: triallyl isocyanurate; product number TAIC manufactured by Mitsubishi Chemical Corporation;
Organic Compound 2 having a polymerizable unsaturated group: tricyclodecane dimethanol dimethacrylate; product number DCP manufactured by Shin-Nakamura Chemical Co., Ltd.;
Elastomer 1: styrene-hydrogenated diene copolymer; product name SEPTON™ V9827 manufactured by Kuraray Co., Ltd.;
Elastomer 2: styrene-hydrogenated diene copolymer; product name Tuftec™ N504 manufactured by Asahi Kasei Corporation;
Elastomer 3: styrene-non-hydrogenated diene copolymer; product name HYBRAR™ 5125 manufactured by Kuraray Co., Ltd.;
Flame retardant: phosphorus-containing flame retardant; product number PQ-60 manufactured by DKS Co., Ltd.;
Inorganic filler: spherical silica surface-treated with vinyl silane; product number 0.5 μm SV-CT1 (25% toluene containing slurry) manufactured by Admatechs;
Fibrous filler 1: QCP (0.2 dTex×0.2 mm); product number QCP manufactured by UBE EXSYMO Co., Ltd.; a fibrous filler containing olefin as an organic polymer; having a fiber diameter Lc of 5 μm and a fiber length L1 of 0.2 mm; a fiber length L1/fiber diameter Lc ratio of 40;
Fibrous filler 2: product number QCE manufactured by UBE EXSYMO Co., Ltd.; a fibrous filler containing olefin as an organic polymer; having a fiber diameter Lc of 5 μm and a fiber length L1 of 0.2 mm; a fiber length L1/fiber diameter Lc ratio of 40;
Fibrous filler 3: PF E301; product number PF E301 manufactured by Nitto Boseki Co., Ltd.; a fibrous filler containing glass as an inorganic material; having a fiber diameter Lc of 10 μm and a fiber length L1 of 0.3 mm; a fiber length L1/fiber diameter Lc ratio of 30;
Organic radical compound: 2,2,6,6-tetramethylpiperidine 1-oxyl; and
Peroxide: di-t-amyl peroxide.

2. Evaluation

The composition was subjected to the following evaluation tests. The results are summarized in Table 1.

(1) Varnish Viscosity

A resin varnish having a solid content concentration of 45% by mass was prepared by adding toluene as a solvent to the composition. The viscosity of this resin varnish at 30° C. was measured with a B-type rotational viscometer under the condition including the number of revolutions of 30 rpm.

(2) Lowest Melt Viscosity

A resin varnish having a solid content concentration of 45% by mass was prepared by the same method as in the “(1) Varnish viscosity” section described above. This resin varnish was applied onto a polyethylene terephthalate film having a thickness of 38 μm by using a comma coater and a dryer connected thereto, and then heated at 120° C. for 3 minutes, thereby forming a resin sheet to thickness of 100 μm on the polyethylene terephthalate film.

The lowest melt viscosity of this resin sheet was measured by a constant temperature method using a high-performance flow tester (model number CFT-500D manufactured by Shimadzu Corporation) under the condition including a temperature of 170° C. and a load of 20 kgf (=196 N).

(3) Tear Strength

A resin varnish having a solid content concentration of 45% by mass was prepared by the same method as in the “(1) Varnish viscosity” section described above. This resin varnish was applied onto a polyethylene terephthalate film having a thickness of 38 μm by using a comma coater and a dryer connected thereto, and then heated at 120° C. for 3 minutes, thereby forming a resin sheet to thickness of 100 μm on the polyethylene terephthalate film.

The tear strength of this resin sheet was measured by the angle tear method defined by JIS 1(7128-3.

(2) Dielectric Properties (Relative Dielectric Constant and Dielectric Loss Tangent)

A resin varnish having a solid content concentration of 45% by mass was prepared by the same method as in the “(1) Varnish viscosity” section described above. This resin varnish was applied onto a polyethylene terephthalate film having a thickness of 38 μm by using a comma coater and a dryer connected thereto, and then heated at 120° C. for 3 minutes, thereby forming a resin sheet to thickness of 100 μm on the polyethylene terephthalate film.

Two sheets of copper foil, each having a thickness of 18 μm, were arranged so that their glossy surfaces faced each other, and a resin sheet was interposed between the two sheets of copper foil. A sample was formed by hot-pressing these under the condition including 200° C. and 2 MPa for 2 hours. This sample was subjected to an etching process to remove the sheets of copper foil from both sides and thereby obtain a test piece made of a cured product of the resin sheet. The relative dielectric constant and dielectric loss tangent of this test piece were measured at a test frequency of 10 GHz based on IPC TM-650 2.5.5.5.

(5) Thermal Stability of Dielectric Loss Tangent

The sample that had been formed as described in the “(4) Dielectric properties” section was left in an atmosphere at a temperature of 150° C. for 200 hours and then cooled to room temperature. Then, the dielectric loss tangent of this sample was measured. The difference ΔDf (=Df₁−Df₀) between a measured value Df₁ obtained in this manner and the measured value Dfo of the dielectric loss tangent obtained in the “(4) Dielectric properties” section described above was calculated.

(6) Coefficient of Linear Expansion

A resin varnish having a solid content concentration of 45% by mass was prepared by the same method as in the “(1) Varnish viscosity” section described above. This resin varnish was applied onto a polyethylene terephthalate film having a thickness of 38 μm by using a comma coater and a dryer connected thereto, and then heated at 120° C. for 3 minutes, thereby forming a resin sheet to thickness of 100 μm on the polyethylene terephthalate film.

By cutting a cured product that had been obtained by heating the resin sheet at 200° C. for 120 minutes under a vacuum, a sample for evaluation with dimensions of 5 mm×20 mm in plan view was formed. The coefficient of linear expansion and the glass transition temperature of this sample were measured using a thermomechanical analyzer (“TMA/S S6100” manufactured by SII Nanotechnology Inc.) under the condition including a chuck length of 15 mm, a load of 10 g, and a temperature increase rate of 10° C./min until the temperature reached 350° C. Note that the coefficient of thermal expansion (α1) is the value of the coefficient of linear expansion below the glass transition temperature of the cured product, and the coefficient of thermal expansion (average in 30-250° C.) is the average value of the coefficient of thermal expansion calculated based on the result of measurement within the range from 30° C. to 250° C. If the coefficient of thermal expansion (α1) is equal to or less than 40 ppm/° C., evaluation may be made that the increase in the coefficient of linear expansion is reduced. If the coefficient of thermal expansion (average in 30-250° C.) is equal to or less than 50 ppm/° C., evaluation may be made that the increase in the coefficient of linear expansion is reduced.

TABLE 1

| | | | | | | | | | | | Compar- |
|---|---|---|---|---|---|---|---|---|---|---|---|
| | | | | | | | | | | | ative |
| | | Examples | | | | | | | | | example |
| | | 1 | 2 | 3 | 4 | 5 | 6 | 7 | 8 | 9 | 1 |
| Mate- | Copolymer 1 | 24 | 24 | 24 | | | 24 | 24 | 24 | 24 | 24 |
| rial/ | Copolymer 2 | | | | 24 | 24 | | | | | |
| parts | Modified PPE 1 | 36 | 36 | 36 | 36 | 36 | | 36 | 36 | 36 | 36 |
| by | Modified PPE 2 | | | | | | 36 | | | | |
| mass | Organic compound | 10 | 10 | 10 | 10 | 10 | 10 | | 10 | 10 | 10 |
| | 1 w/polymerizable | | | | | | | | | | |
| | unsaturated group | | | | | | | | | | |
| | Organic compound | | | | | | | 10 | | | |
| | 2 w/polymerizable | | | | | | | | | | |
| | unsaturated group | | | | | | | | | | |
| | Elastomer 1 | 30 | 30 | 30 | 30 | 30 | 30 | 30 | | | 30 |
| | Elastomer 2 | | | | | | | | 30 | | |
| | Elastomer 3 | | | | | | | | | 30 | |
| | Flame retardant | 50 | 50 | 50 | 50 | 50 | 50 | 50 | 50 | 50 | 50 |
| | Inorganic filler | 250 | 250 | 250 | 250 | 250 | 250 | 250 | 250 | 250 | 250 |
| | Fibrous filler 1 (or- | 6 | | | | | | | | 6 | |
| | ganic polymer fiber) | | | | | | | | | | |
| | Fibrous filler 2 (or- | | 6 | 3 | | | | | | | |
| | ganic polymer fiber) | | | | | | | | | | |
| | Fibrous filler 3 | | | | 6 | 12 | 6 | 6 | 6 | | |
| | (inorganic fiber) | | | | | | | | | | |
| | Organic radical | 0.8 | 0.8 | 0.8 | 0.8 | 0.8 | 0.8 | 0.8 | 0.8 | 0.8 | 0.8 |
| | compound | | | | | | | | | | |
| | Peroxide | 5.4 | 5.4 | 5.4 | 5.4 | 5.4 | 5.4 | 5.4 | 5.4 | 5.4 | 5.4 |
| Eval- | Varnish | 7.3 | 9.3 | 8.5 | 12.5 | 15.6 | 15.4 | 11.3 | 20.5 | 8.2 | 4.2 |
| uation | viscosity (Pa · s) | | | | | | | | | | |
| | Lowest melt | 11.200 | 10.800 | 12.100 | 23.500 | 31.100 | 26.300 | 24.500 | 35.100 | 10.500 | 15.300 |
| | viscosity (Pa · s) | | | | | | | | | | |
| | Tear strength (N) | 0.26 | 0.28 | 0.23 | 0.27 | 0.31 | 0.29 | 0.26 | 0.33 | 0.24 | 0.11 |
| | Relative dielectric | 2.77 | 2.77 | 2.76 | 2.84 | 2.89 | 2.84 | 2.88 | 2.85 | 2.78 | 2.75 |
| | constant: Dk | | | | | | | | | | |
| | Dielectric loss | 0.0012 | 0.0013 | 0.0013 | 0.0017 | 0.0019 | 0.0017 | 0.0019 | 0.0015 | 0.0015 | 0.0013 |
| | tangent: Df | | | | | | | | | | |
| | Thermal stability of | 0.0014 | 0.0013 | 0.0012 | 0.0012 | 0.0013 | 0.0012 | 0.0017 | 0.0011 | 0.0056 | 0.0014 |
| | dielectric loss | | | | | | | | | | |
| | tangent: ΔDf | | | | | | | | | | |
| | Coefficient of ther- | 30 | 32 | 35 | 34 | 31 | 36 | 33 | 30 | 31 | 33 |
| | mal expansion: αl | | | | | | | | | | |
| | Coefficient of ther- | 53 | 56 | 58 | 58 | 56 | 59 | 52 | 51 | 50 | 53 |
| | mal expansion: av- | | | | | | | | | | |
| | erage in 30-250° C. | | | | | | | | | | |
| | Glass transition | 239 | 235 | 228 | 223 | 225 | 221 | 231 | 246 | 234 | 242 |
| | temperature (° C.) | | | | | | | | | | |

1. A thermosetting resin composition containing
an ethylene-propylene-diene copolymer (A),
a terminal-modified polyphenylene ether compound (B),
an inorganic filler (C),
a styrene-based elastomer (D), and
a fibrous filler (E).

2. The thermosetting resin composition of claim 1, wherein
the fibrous filler (E) has a fiber diameter Lc equal to or less than 10 μm and a fiber length L1 equal to or less than 1 mm, and
a ratio of the fiber length L1 to the fiber diameter Lc is equal to or greater than 10 and equal to or less than 10000.

3. The thermosetting resin composition of claim 1, wherein
the fibrous filler (E) includes a fibrous filler (E1) having an organic polymer.

4. The thermosetting resin composition of claim 3, wherein
the organic polymer contains polyolefin.

5. The thermosetting resin composition of claim 1, wherein
the organic filler (C) contains silica subjected to surface treatment with a polymerizable organic compound.

6. The thermosetting resin composition of claim 1, wherein
the styrene-based elastomer (D) contains a styrene-hydrogenated diene copolymer (D1).

7. The thermosetting resin composition of claim 6, wherein
the styrene-based elastomer (D) either contains no styrene-non-hydrogenated diene copolymer (D2) or contains a styrene-non-hydrogenated diene copolymer (D2), and
content of the styrene-non-hydrogenated diene copolymer (D2) with respect to the styrene-based elastomer (D) is equal to or less than 5% by mass.

8. The thermosetting resin composition of claim 1, further containing an organic compound (F) having a polymerizable unsaturated bond.

9. The thermosetting resin composition of claim 1, further containing a peroxide (G).

10. The thermosetting resin composition of claim 1, further containing a flame retardant (H).

11. The thermosetting resin composition of claim 1, further containing a solvent.

12. A resin sheet containing an uncured product or semi-cured product of the thermosetting resin composition of claim 1.

13. A sheet of metal foil with resin, comprising a sheet of metal foil, and a resin layer laid on top of the sheet of metal foil,
the resin layer containing an uncured product or semi-cured product of the thermosetting resin composition of claim 1.

14. A sheet of metal foil with resin, comprising: a sheet of metal foil; a first resin layer stacked on the sheet of metal foil; and a second resin layer stacked on the first resin layer,
the first resin layer containing at least one component selected from the group consisting of a liquid crystal polymer resin, a polyimide resin, a polyamide imide resin, a fluorocarbon resin, and a polyphenylene ether resin,
the second resin layer containing an uncured product or semi-cured product of the thermosetting resin composition of claim 1.

15. A metal-clad laminate comprising: an insulating layer; and a sheet of metal foil laid on top of the insulating layer,
the insulating layer containing a cured product of the thermosetting resin composition of claim 1.

16. A printed wiring board comprising an insulating layer and conductor wiring,
the insulating layer containing a cured product of the thermosetting resin composition of claim 1.

17. The thermosetting resin composition of claim 2, wherein
the fibrous filler (E) includes a fibrous filler (E1) having an organic polymer.

18. The thermosetting resin composition of claim 17, wherein
the organic polymer contains polyolefin.

19. The thermosetting resin composition of claim 2, wherein
the organic filler (C) contains silica subjected to surface treatment with a polymerizable organic compound.

20. The thermosetting resin composition of claim 3, wherein
the organic filler (C) contains silica subjected to surface treatment with a polymerizable organic compound.
